(19) United States
(12) Patent Application Publication
(10) Pub. No.: US 2008/0204415 A1
(43) Pub. Date: Aug. 28, 2008

(54) Optical Coordinates Input Apparatus, Optical Sensor Module and Method For Assembling Thereof

(76) Inventors: Hyun-Joo Jung, Gyeonggi-do (KR); Sang-Eun Son, Gyeonggi-do (KR)

Correspondence Address: DALY, CROWLEY, MOFFORD & DURKEE, LLP, SUITE 301A, 354A TURNPIKE STREET, CANTON, MA, 02021-2714, US

(21) Appl. No.: 11/815,027

(22) PCT Filed: Mar. 3, 2006
(86) PCT No.: PCT/KR2006/000730

§ 371 Date: Jul. 30, 2007

(30) Foreign Application Priority Data
Mar. 4, 2005 (KR) 10-2005-0017954
May 13, 2005 (KR) 10-2005-0039941
Jul. 7, 2005 (KR) 2005-0061300

(51) Int. Cl. G06F 3/033; H01L 31/12; H01L 33/00

(52) U.S. Cl. 345/166; 257/82; 438/25

(57) ABSTRACT

In an optical coordinate input apparatus, a body includes an opening portion adjacent to a reflective surface, and a circuit board is installed in the body. An optical sensor module is installed in the body adjacent to the opening and separately from the circuit board, and has a light-receiving surface, of which an incident optical axis is inclined with respect to the reflective surface, and a light source, of which an exiting optical axis is inclined with respect to the incident optical axis. Accordingly, the circuit board is easily positioned in the body irrespective of optical and mechanical characteristics of the optical sensor module.

### TECHNICAL FIELD

The present invention relates to an optical coordinate input apparatus, an optical sensor module and a method of assembling the same, and more particularly, to a micro-optical apparatus in which a light source and an optical sensor module are integrated together with each other, and a method of manufacturing the same.

### BACKGROUND ART

A mouse, which is generally used as an input device for a computer system, transfers coordinates of a cursor or a pointer to a central processing unit (CPU) of the computer system. Nowadays, various types of mouses are used in computer systems: a ball mouse, an optical mouse, a fingerprint optical mouse, a pen-type optical mouse, etc.

When foreign matter sticks to a ball of the ball mouse or the ball of the ball mouse is severely worn down, a sensor of the ball mouse may not accurately detect the motion of the ball. The optical mouse has been developed so as to solve the above problems. The optical mouse detects a signal in accordance with a motion of an optical image on a mouse pad, and transforms the detected signal into X- and Y-coordinate values. A variation of the coordinate values is displayed as a movement of a cursor of the optical mouse on a monitor.

An optical mouse for a computer system is exemplarily displayed in Korean Patent No. 399639, Korean Utility Model No. 315274, U.S. Patent Application Publication Nos. 2002/0080117, 2003/0142075, 2004/0084610, 2004/0212592, and 2005/0264532, Japanese Patent Laid-Open Publication No. 1999/272417 and Japanese Utility Model No. 3113650. The optical mouse has a sufficient volume and size to be grasped by an operator's hand, i.e., a palm and fingers of the operator, and various parts and devices of the optical mouse are positioned in a space corresponding to the volume. A light is generated from a light source and is reflected from a light guide one to three times. Finally, the reflected light reflected from the light guide is incident on a mouse pad. The above conventional structure of the optical mouse requires so many parts and a large space. Therefore, the conventional optical mouse is difficult to reduce in volume and size.

Japanese Utility Model No. 3113650 discloses that the light generated from a light source is directly incident on a reflective surface without a lens or a light guide, and the reflected light reflected from the reflective surface is received by a receiving unit, thereby reducing the number of the parts of the optical mouse.

Japanese Patent Laid-Open Publication No. 2005-197717 discloses an image sensor package manufactured by a flip-chip bonding process.

Korean Patent Laid-Open Publication No. 2005-0113311, Korean Patent No. 489959 and Korean Utility Model No. 385582 disclose a pen-type optical coordinate input system.

The conventional pen-type optical mouse includes a long barrel corresponding to a body of the pen-shaped optical mouse and an image sensor for detecting a reflection signal, so that an optical path between a light source, such as a light-emitting diode (LED), and the image sensor is necessarily long. In addition, an optical axis of the LED does not coincide with a central axis of the body of the pen-shaped optical mouse, and somewhat crosses the central axis of the body, so that the reflected light cannot travel along the central axis of the body of the pen-shaped optical mouse. Accordingly, in the conventional pen-shaped optical mouse, most of the light cannot reach the image sensor, and is lost as a result.

A generic optical mouse is usually operated in such a way that a bottom surface of the body of the optical mouse makes contact with the mouse pad, so that operation characteristics of the generic optical mouse are almost the same irrespective of an individual operator. However, the pen-type optical mouse is operated as if an operator is writing something on a mouse pad with a pen, and a habit or a manner of grasping a pen very much varies according to different individual operators. For example, different operators have different grasping angles of the pen. Accordingly, optical characteristics and optical sensitivity of the pen-type optical mouse are very much influenced by an individual operation manner, and the performance of the pen-type optical mouse is very much dependent on the individual operator.

In a structural view, the conventional pen-type optical mouse includes a microcircuit board positioned in a long and hollow body, an image sensor chip and a light-emitting device chip mounted on the microcircuit board, and an optical structure mounted on the image sensor chip and the light-emitting device chip. However, the image sensor is directly mounted on the circuit board, and is arranged in a long and narrow shape in accordance with a pen shape of the body of the optical mouse. Accordingly, the image sensor occupies most of the inner space of the body, so that other parts or additional parts of the pen-shaped optical mouse necessarily require an increase of the body size.

In general, the manufacturing costs of an optical coordinate input system is largely dependent on the manufacturing costs of an optical sensor module thereof including an image sensor. Therefore, reduction of the manufacturing costs of the optical sensor module has much effect on the reduction of the manufacturing costs of the optical mouse.

The conventional optical sensor module and an assembling process for manufacturing the same have the following problems:
1) The substrate and the lens holder are required to be bonded to each other using an epoxy bonding agent, because the epoxy bonding agent can sufficiently firmly bonds the lens holder to the substrate while simultaneously sealing off the image sensor from surroundings. The image sensor is positioned in a receiving space defined by the lens holder and the substrate. When minute particles and dust are deposited on a light-receiving surface of the image sensor, a fatal image defect is generated in the optical sensor module due to the minute particles and dust, thereby causing a failure of the optical mouse. Accordingly, the receiving space necessarily is required to be sealed off from surroundings as well as being firmly bonded to the substrate, and the epoxy bonding agent most satisfies the above requirements. As a result, the epoxy bonding agent is indispensable for the conventional optical sensor module.
2) The epoxy bonding agent is hardened at a temperature of about 100° C. to about 120° C., so that the barrel integrated together with a plastic lens in one body cannot be used in the conventional optical sensor module due to a lens deformation caused by a high temperature. Physical and optical characteristics of the plastic lens may be indeterminate at a temperature above about 85° C. For those reasons, the barrel and the lens holder are formed into a separable structure, and are assembled to each other in the assembly process by a screw joint so as to adjust the focal distance of the lens.
3) There are many limitations for reducing a length of the optical sensor module. A thickness of the epoxy bonding agent, a thickness of the infrared (IR) cut filter glass, a bottom thickness of the separable barrel and a minimum height for the focal distance adjustment may put limitations on downsizing the optical sensor module.

As described above, the conventional optical sensor module of the optical coordinate input system, such as the optical mouse for a computer system, is very difficult to reduce in size and has low productivity due to the focal distance adjustment, all of which increases manufacturing costs of the optical sensor module.

Korean Patent Laid-Open Publication No. 2005-26487 discloses a lens holder of which a reference surface makes contact with a top surface of the image sensor. However, the above lens holder has a problem in that cracks can be easily generated on the top surface of the image sensor when variable forces are applied on the image sensor.

### DISCLOSURE OF THE INVENTION

Technical Problem

The present invention provides an optical coordinate input apparatus including a light source and an optical sensor module integrated together with each other in one body to thereby have a sufficiently reduced size.

The present invention also provides a pen-type optical coordinate input apparatus including a reference face at a pointed portion, thereby guiding an degree of inclination of a pen-shaped body of the optical coordinate input apparatus.

The present invention still also provides a pen-type optical coordinate input apparatus including an optical sensor module integrated with a light source in one body at a pointed portion, thereby shortening a focal distance thereof.

The present invention further still also provides an optical sensor module integrated together with a light source in one body and a method of assembling the same, thereby reducing size and manufacturing costs of the optical sensor module.

The present invention further still also provides a method of assembling an optical sensor module without a focal distance adjustment.

Technical Solution

An optical coordinate input apparatus, according to an example embodiment of the present invention, includes a body including an opening portion adjacent to a reflective surface, a circuit board installed in the body and an optical sensor module that is installed in the body adjacent to the opening and separate from the circuit board. The optical sensor module has a light-receiving surface, of which an incident optical axis is inclined with respect to the reflective surface and a light source, of which an exiting optical axis is inclined with respect to the incident optical axis.

As an example, a shape of the body includes a pen and the optical sensor module is installed at a pointed portion of the pen-shaped body, and the exiting optical axis is inclined with respect to the incident optical axis at an angle of about 20°±5°.

The optical sensor module includes a module substrate on which a lens holder including the light source and at least one lens and an image sensor including the light-receiving surface are installed. The lens holder includes a barrel having a receiving groove for receiving a light source at an outer surface thereof and a box-shaped receiving unit that is combined together with the barrel as one body. A bottom surface of the receiving unit is arranged perpendicular with respect to an optical axis of the lens and makes contact with an edge portion of a top surface of the module substrate, to thereby function as a reference face for a focal distance between the lens and the light-receiving surface, and a plurality of protrusions downwardly extends from an inner edge portion of the bottom surface of the receiving unit to a length larger than a thickness of the module substrate, so that each of the protrusions penetrates the module substrate and an end portion of each of the protrusions is protruded from the bottom surface of the module substrate. A plurality of insertion holes through which the protrusions are inserted is formed at an edge portion of the module substrate. The lens holder is bonded to the module substrate by pressing, adhesion, locking or thermal bonding.

An optical sensor module for an optical coordinate input apparatus, according to another example embodiment of the present invention, includes a module substrate of which a top surface is substantially perpendicular to an optical axis, a lens holder including a barrel having a receiving groove formed at an outer surface thereof and a box-shaped receiving unit that is combined together with the barrel as one body, a light source received in the receiving groove, a lens installed in the barrel, and an image sensor positioned in a sealed space between the receiving unit and the module substrate and mounted on a top surface of the substrate. A bottom surface of the receiving unit includes a reference surface that is substantially perpendicular with respect to the optimal axis, and makes direct contact with a top surface of the substrate, and a bonding surface that is spaced apart from the top surface of the substrate by a predetermined gap distance and makes direct contact with a bonding agent in the gap distance. The lens of the present embodiment includes a lens combination including at least one lens. When the lens combination includes a plurality of lenses, at least one light-shielding plate may be interposed between the lenses. In addition, an infrared (IR) cut filter may be coated on a surface of at least one lens.

The module substrate includes an extension portion outwardly extending over the lens holder and a switch on the extension portion. The body is shaped into a pen, and a pen point is positioned at a pointed portion of the body such that the pen point is vertically protruded from the reference surface and moves forwardly and backwardly, so that the switch is operated in accordance with the movement of the pen point.

A camera module may be further installed in the body of the optical coordinate input apparatus.

The circuit board of the optical coordinate input apparatus includes a wireless transmission module for transmitting detected coordinates, an internal battery for supplying power to the circuit board, and a plurality of terminals for connecting an external power source to the internal battery. As described above, a downsized optical sensor module may be installed inside of the body of the optical coordinate input apparatus separately from the circuit board, so that a reduced space is required for the optical sensor module.

According to still another example embodiment of the present invention, there is provided a method of assembling an optical sensor module. At first, a lens is combined with a lens holder, and an image sensor is mounted on each module substrate of a module substrate array. The lens holder including the lens is combined with each of the module substrates of the module substrate array. Optical characteristics of each optical sensor module are measured on each module substrate. The module substrate array is separated into individual module substrates. Accordingly, assembly time of the optical sensor module is sufficiently reduced as compared with a conventional measurement process in which an optical test is individually performed on each of the optical sensor modules. As a result, assembly costs are sufficiently reduced and an automatic optical measurement is facilitated.

An optical coordinate input apparatus for a portable electronic device, such as a cellular phone or a notebook computer, is provided to include an optical sensor module according to the present invention. The optical coordinate input apparatus includes a housing including a fixing member, a moving member installed in the housing and which moves along upward, downward, leftward or rightward directions, and an optical sensor module installed in the moving member. The optical sensor module irradiates onto the fixing member and detects a reflected image reflected from the fixing member.

As a modified optical coordinate input apparatus includes a fixing member including a receiving hole, a cantilever of which an end portion is connected to the fixing member, and a rotating ball rotatably positioned in the receiving hole of the fixing member and the holding groove of the cantilever. The cantilever includes a holding groove having a transparent window on an inner surface thereof. The apparatus includes an optical sensor module for irradiating a light to the rotating ball through the transparent window and detecting a reflected image reflected from the rotating ball.

Effect of the Invention

According to the present invention, a sufficiently downsized optical sensor module including a light source can be mounted on an optical coordinate input apparatus at a low cost, so that the optical sensor module is mounted on the optical coordinate input apparatus without having to be limited by the size of an inner space of the body.

In addition, a light path is remarkably shortened in the optical mouse including the image sensor module, thereby reducing light loss and improving reliability of the operation of the optical mouse. Furthermore, some modules for additional functions may be added to the optical mouse of the present invention because the image sensor of the present invention is formed to a sufficiently small size.

### BRIEF DESCRIPTION OF THE DRAWINGS

The above and other advantages of the present invention will become more apparent by describing in detail example embodiments thereof with reference to the accompanying drawings, in which:

FIG. 1 is a cross-sectional view illustrating a pen-type optical mouse according to a first example embodiment of the present invention;

FIG. 2 is an enlarged view illustrating a pointed portion of a body of the pen-type optical mouse shown in FIG. 1;

FIG. 3 is a plan view illustrating an optical sensor module according to a first example embodiment of the present invention;

FIG. 4 is a cross-sectional view taken along a line I-I′ shown in FIG. 3;

FIG. 5 is a bottom view illustrating the optical sensor module shown in FIG. 3;

FIG. 6 is a plan view illustrating an optical sensor module according to a second example embodiment of the present invention;

FIG. 7 is a cross-sectional view taken along the line II-II′ of FIG. 6;

FIG. 8 is a plan view illustrating an optical sensor module according to a third example embodiment of the present invention;

FIG. 9 is a cross-sectional view taken along the line III-III′ of FIG. 8;

FIG. 10 is an exploded perspective view illustrating the optical sensor module shown in FIG. 8;

FIG. 11 is a plan view illustrating an optical sensor module according to a fourth example embodiment of the present invention;

FIG. 12 is a cross-sectional view taken along the line IV-IV′ of FIG. 11;

FIG. 13 is an exploded perspective view illustrating the optical sensor module shown in FIG. 11;

FIG. 14 is a plan view illustrating an optical sensor module according to a fifth example embodiment of the present invention;

FIG. 15 is a cross-sectional view taken along the line V-V′ of FIG. 14;

FIG. 16 is a flow chart illustrating a method of assembling the optical sensor module according to an example embodiment of the present invention;

FIG. 17 is a view illustrating a module substrate array according to an example embodiment of the present invention;

FIG. 18 is a view illustrating an individual optical sensor module separated from the module substrate array shown in FIG. 17;

FIG. 19 is a cross-sectional view illustrating a slide-type optical coordinate input apparatus according to an example embodiment of the present invention; and

FIG. 20 is a cross-sectional view illustrating a ball-type optical coordinate input apparatus according to an example embodiment of the present invention.

### BEST MODE FOR CARRYING OUT THE INVENTION

It should be understood that the example embodiments of the present invention described below may be varied modified in many different ways without departing from the inventive principles disclosed herein, and the scope of the present invention is therefore not limited to these particular following embodiments. Rather, these embodiments are provided so that this disclosure will be through and complete, and will fully convey the concept of the invention to those skilled in the art by way of example and not of limitation.

Hereinafter, the present invention will be described in detail with reference to the accompanying drawings.

A. Pen-Type Optical Mouse

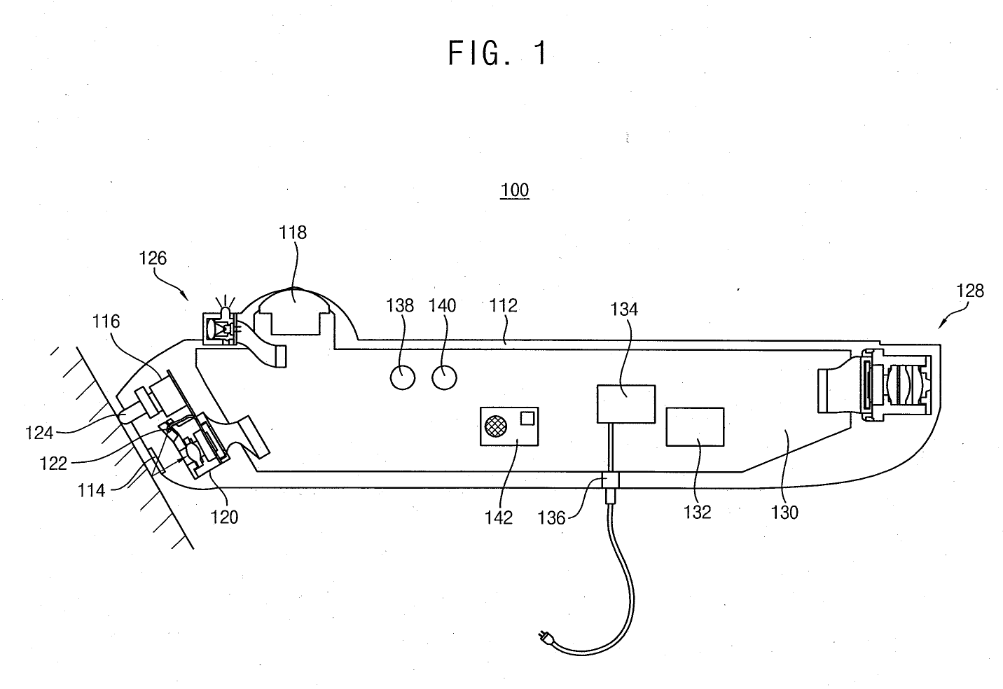

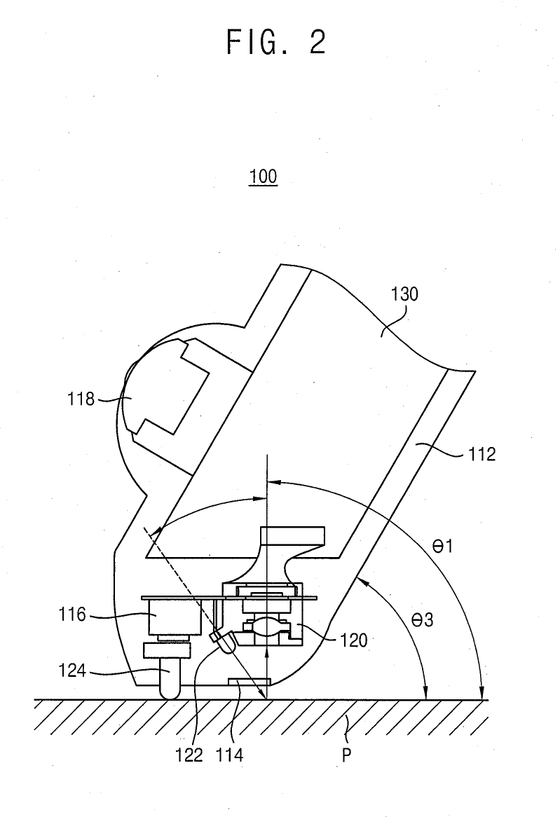

FIG. 1 is a cross-sectional view illustrating a pen-type optical mouse according to a first example embodiment of the present invention, and FIG. 2 is an enlarged view illustrating a pointed portion of a body of the pen-type optical mouse shown in FIG. 1.

Referring to FIG. 1, the pen-type optical mouse 100 according to the first example of the present invention includes a pen-shaped body 112 including an opening 114, a selection button 116, a scroll jog button 118, an optical sensor module 120, a light source such as a light-emitting diode (LED) 122, a pen point 124, a pointer module 126 and a camera module 128.

A circuit board 130 includes a wireless transmitter module 132, an internal battery 134, and a power terminal 136. The wireless transmitter module 132 includes an infrared light transmitter module, a high-frequency wave transmitter module and a short-range digital communication device using the Bluetooth wireless specification. As an example embodiment, the power terminal includes a Universal Serial Bus (USB) port and power is provided by a USB cord.

The pen-shaped body 112 is approximately formed into a cylindrical shape and includes a front surface facing a mouse pad P. In particular, a front portion of the body 112 including the front surface is slightly inclined with respect to a central axis of the cylinder. The opening 114 is formed on the front surface of the body 112, and the light generated from the LED 122 is irradiated onto the mouse pad P through the opening 114. The front surface of the body 112 functions as a reference surface and is substantially parallel with the mouse pad P.

Referring to FIG. 2, a sidewall of the body 112 is inclined with respect to the mouse pad P at a third angle θ₃ varying in a range of about 60±5°. The optical sensor module 120 is positioned at the pointed portion of the body 112 separately from the circuit board 130. As an example embodiment, the optical sensor module 120 is disposed over and around the opening 114. That is, the optical sensor module 120 is positioned inside of the front portion of the body 112, so that the intensity of the light received by the optical sensor module 120 is almost constant irrespective of the third angle θ₃ between the mouse pad P and the body 112 of the pen-type optical mouse 100. As an example embodiment, a central axis of the LED 122 is inclined with respect to an optical axis of the optical sensor module 120 at a second angle θ₂ varying in a range of about 20±5°, and the optical axis of the optical, sensor module 120 is inclined with respect to the front surface of the body 112 substantially parallel with the mouse pad P at a first angle θ₁ varying in a range of about 90±5°.

The selection button 116 is positioned on the body 112 adjacent to the optical sensor module 120. A pen point 124, which is a tip for pressing the selection button 116 when making contact with the mouse pad P, is installed in the body 112, and a front end of the pen point 124 is protruded from the front portion of the body 112. Particularly, an axis of the pen point 124 is substantially parallel with an optical axis of an incident light. As an example embodiment, the pen point 124 is protruded from the front portion of the body 112 to a protrusion length of about 3 mm to about 4.5 mm, so that the front portion of the body 112 is spaced apart from the mouse pad P by a distance no more than about 4 mm on condition that the pen point 124 is pressed against the mouse pad P to a distance of about 1 mm.

The scroll jog button 118 is positioned on the body 112. When the scroll jog button 118 is pushed forward for a time, a cursor is accelerated upwardly on a screen for the duration of the push time. In the same way, when the scroll jog button 118 is pulled backwardly for a time, a cursor is accelerated downwardly on a screen for the duration of the pull time. The pointer module 128 is positioned on the front portion of the body 112, and the camera module 128 is positioned on a rear portion of the body 112. Various optional devices, such as an option button 138, a resolution adjustment button 140, and a voice input module 142 including a microphone and a voice chip, may be additionally installed on the circuit board 130.

According to the present example embodiment, the optical sensor module 120 is installed at a pointed portion of the body 112 separately from the circuit board 130, so that a sufficient space for including any other electronic devices may be obtained in the body 112. Accordingly, various circuits may be installed in the optical mouse of the present invention even though the body of the optical mouse is formed into the long and hollow pen shape.

Optical Sensor Module

### Embodiment 1

### Locking Structure Between a Lens Holder and a Module Substrate

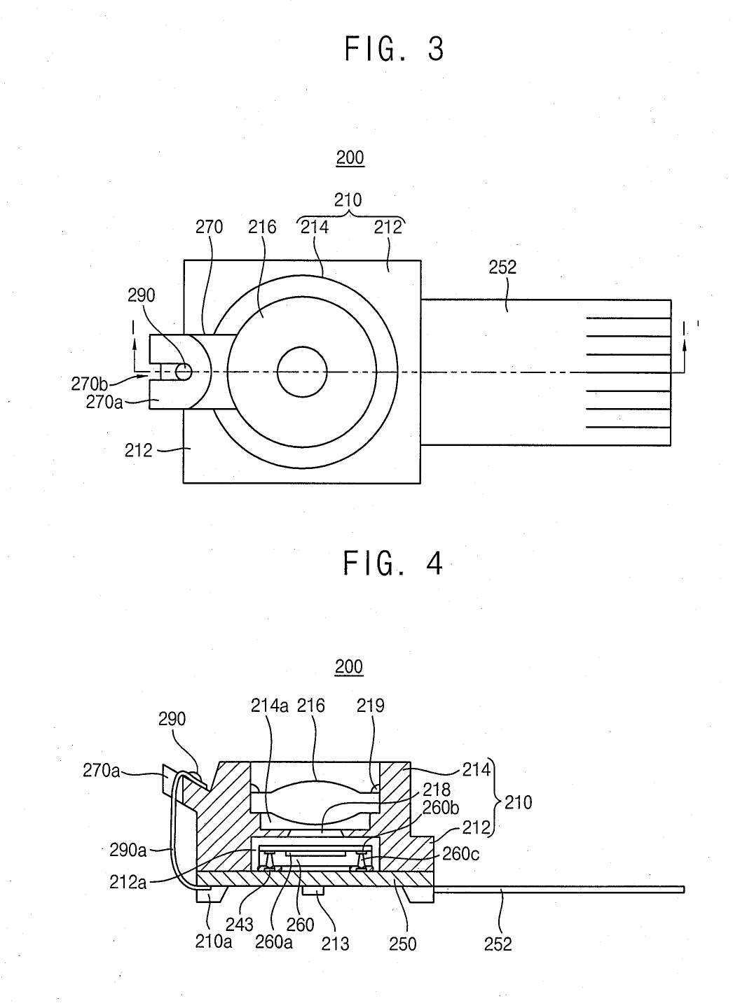

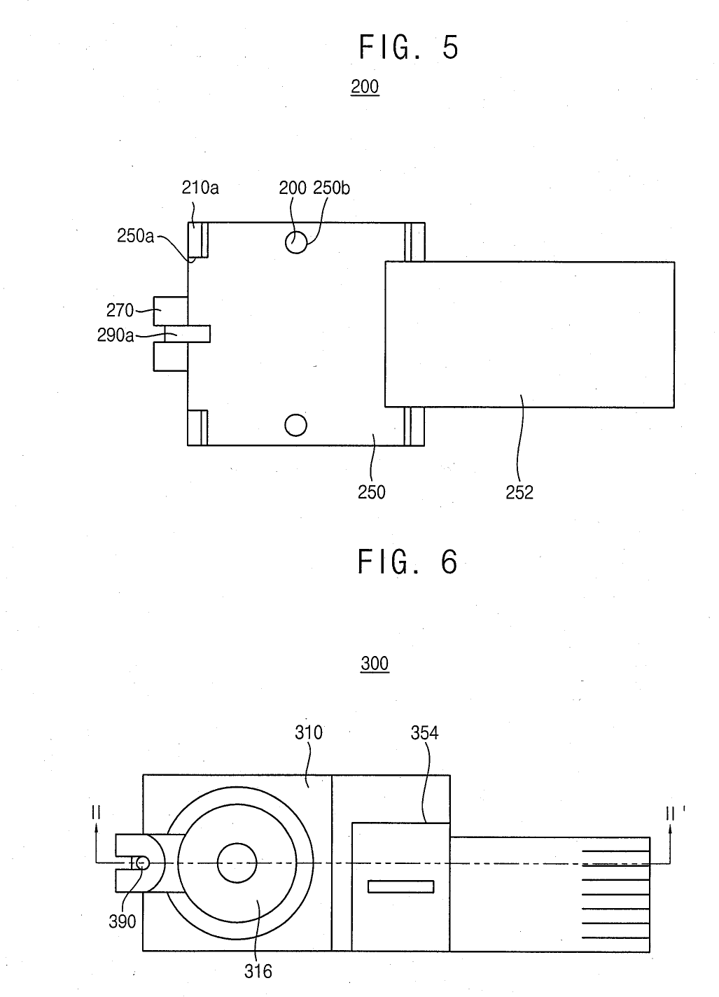

FIG. 3 is a plan view illustrating an optical sensor module according to a first example embodiment of the present invention. FIG. 4 is a cross-sectional view taken along a line I-I′ shown in FIG. 3, and FIG. 5 is a bottom view illustrating the optical sensor module shown in FIG. 3.

Referring to FIGS. 3 to 5, the optical sensor module 200 of the present example embodiment includes a substrate unit and a lens unit. The lens unit includes a lens holder 210, a lens 216 and a light source 290. The substrate unit includes a module substrate and an image sensor chip 260. The module substrate includes a rigid substrate 250 and a flexible substrate 252.

The rigid substrate 250 has a rectangular outer wall that is approximately the same shape as the rectangular shape of the lens holder 210. A plurality of fixation holes 250a is formed at every corner of the rigid substrate 250, and a plurality of alignment holes 250b is formed at peripheral portions of the rigid substrate 250. As an example embodiment, a central axis line of a receiving surface of the image sensor chip penetrates the center of the alignment holes 250b.

Linear holes are formed in a sensing surface 260a of the image sensor chip 260 to each of pads 260b of the rigid substrate 250. The pad 260b of the rigid substrate 250 functions as an electrical connection port. A plurality of bumps 260c is formed in each of the linear holes, so that the bump 260c makes contact with the pad 260b of the rigid substrate 250. As an example embodiment, an end portion of the bump 260c is shaped into a steeple to thereby facilitate metallic thermal bonding to the pad 260b of the rigid substrate 250.

The lens holder 210 includes a box-shaped receiving unit 212 and a cylindrical barrel 214 disposed on the receiving unit 212. The receiving unit 212 is bonded to the rigid substrate 250 and the barrel 214 includes a lens. A first space 212a is formed in the receiving unit 212, and a second space 214a is formed in the barrel 214. The image sensor chip 260 is positioned in the first space 212a, and the lens 216 is positioned in the second space 214a. A light hole 218 is formed between the receiving unit 212 and the barrel 214, so that the light travels from the lens 216 to the image sensor chip 260 below the lens 216 through the light hole 218.

Accordingly, an intensity of the light that is incident on the image sensor chip 260 varies in accordance with a diameter of the light hole 218. In the present embodiment, the diameter of the light hole 218 is smaller than a diameter of the lens 216.

The lens 216 is received in the second space 214a and is bonded to the lens holder 210 by an ultraviolet light bonding agent 219 coating along an edge portion of the lens 216. The ultraviolet light bonding agent 219 is hardened by irradiation of the ultraviolet light thereto.

A protrusion 210a is downwardly protruded from a bottom surface of the receiving unit 212 of the lens holder 210 at every corner portion thereof, and an end of each protrusion 210a includes a catching portion having an inclined surface. When the lens holder 210 is assembled with the substrate 250, the protrusion 210a is inserted into the fixation hole 250a by being slightly tilted in accordance with the inclined surface of the catching portion. When the protrusion 210a completely penetrates the fixation hole 250a of the substrate 250, the catching portion of the protrusion is caught on the bottom surface of the substrate 250 so that the lens holder 210 is bonded to the substrate 250. That is, the lens holder 210 is strongly bonded to the substrate 250 due to the protrusion 210a including the catching portion.

An alignment bar 213 is downwardly protruded from a bottom surface of the lens holder 210, and a central axis of the alignment bar 213 coincides with an optical axis of the lens. Accordingly, when the alignment bar 213 is inserted into the alignment hole 250b of the substrate 250, the lens is self-aligned with the image sensor chip 260. That is, when the alignment bar 213 is inserted into the alignment hole 250b of the substrate 250, the optical axis of the lens penetrates the center of the receiving surface 260a of the image sensor 260.

A light holder 270 for holding the light source 290 is formed at one side of the barrel 214 of the lens holder 210 as one body. As an example embodiment, the light holder 270 includes a holding protrusion 270a protruded from the barrel 214, and a holding groove 270b at a central portion of the holding protrusion 270a. The light source 290 such as an LED is inserted into the holding groove 270b. The holding protrusion 270a includes a reference surface for a configuration of the light source and the lens, such that the optical axis of the light source is tilted with respect to the central axis of the lens at an angle of about 20±5°. In the present embodiment, the light source 290 is electrically connected to the rigid substrate 250 through a wire 290a.

The module substrate includes the rigid substrate 250 and the flexible substrate 252, and the rigid substrate 250 is electrically connected to surroundings through the flexible substrate 252.

### Embodiment 2

### Locking Structure Between a Lens Holder and a Module Substrate—Switch Type

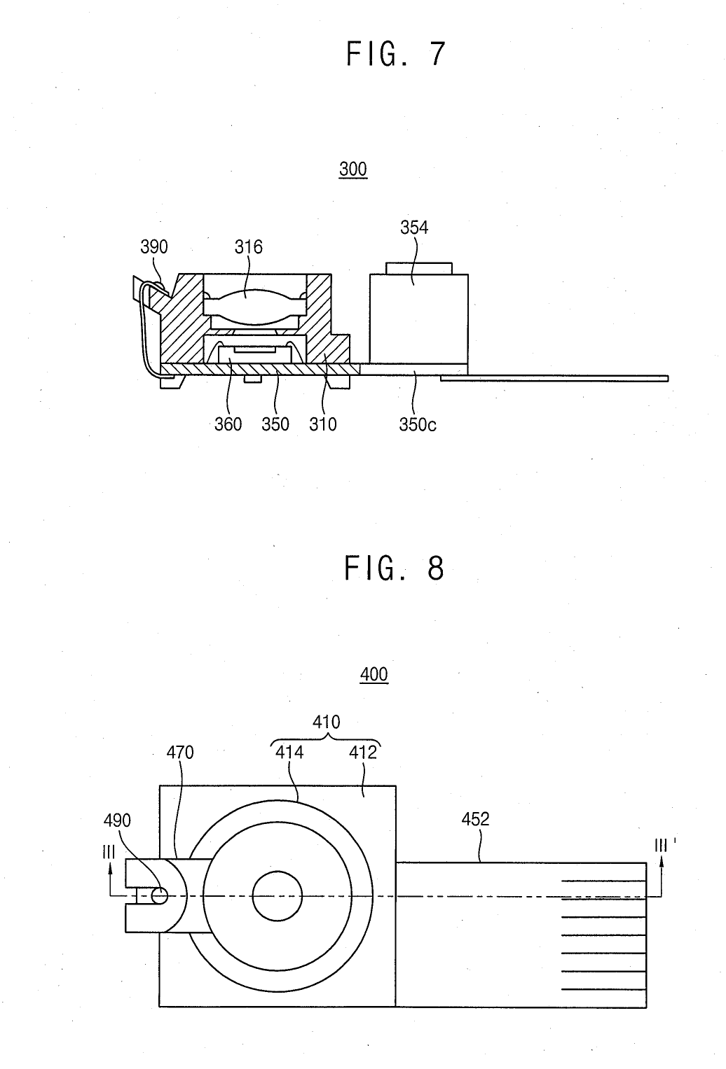

FIG. 6 is a plan view illustrating an optical sensor module according to a second example embodiment of the present invention, and FIG. 7 is a cross-sectional view taken along the line II-II′ of FIG. 6. The optical sensor module in Embodiment 2 is the same as in Embodiment 1 except that the receiving unit of a rigid substrate 350 includes an extension portion 350c and a switch 354 is positioned on the extension portion 350c, and the image sensor chip is mounted on the rigid substrate not by a flip-chip process but by a wire bonding process. The extension portion 350c is extended from the rigid substrate 350 beyond an edge line of the lens holder. In the present embodiment, the remaining elements are substantially the same as those in Embodiment 1, and thus the detailed descriptions of the same elements will be omitted.

### Embodiment 3

### Thermal Bonding Structure Between a Lens Holder and a Module Substrate

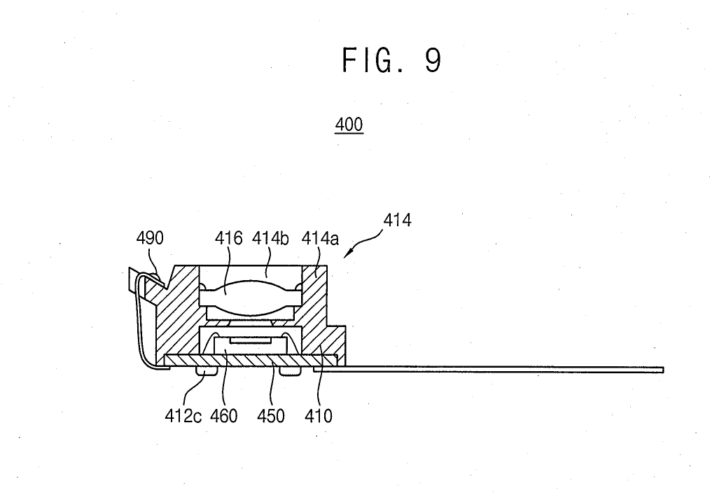

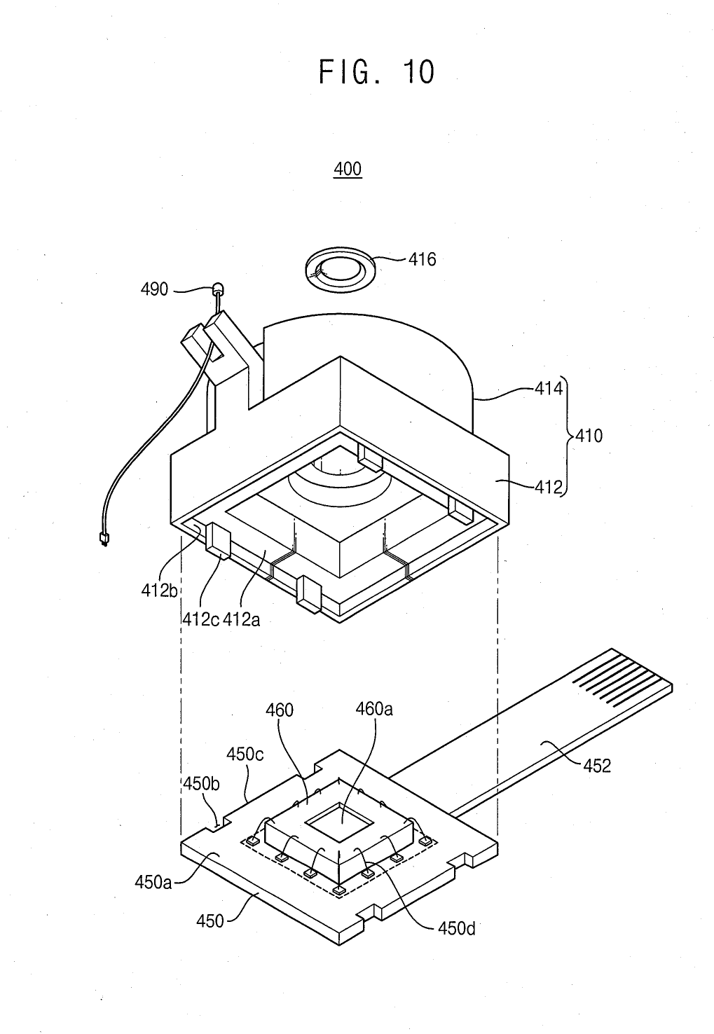

FIG. 8 is a plan view illustrating an optical sensor module according to a third example embodiment of the present invention, and FIG. 9 is a cross-sectional view taken along the line III-III′ of FIG. 8. FIG. 10 is an exploded perspective view illustrating the optical sensor module shown in FIG. 8.

Referring to FIGS. 8 to 10, the optical sensor module 400 in Embodiment 3 includes a lens holder 410, a rigid substrate 450, a flexible substrate 452 and a light source 490.

As an example embodiment, the lens holder 410 is formed into a two-stepped tower structure through an injection molding process, so that the receiving unit 412 is formed simultaneously with the barrel 414 as one body. A bottom surface of the receiving unit 412 includes a reference face 412a. The reference face 412a is substantially horizontal with respect to an optical axis 402, and makes contact with a top surface 450a of an edge portion of the rigid substrate 450. An adjustment for a back-focus is performed on a basis of the reference face 412a.

An extension wall 412b downwardly extends from an edge portion of the receiving unit 412 adjacent to the reference face 412a, and a side surface 450c of the rigid substrate 450 makes surface contact with the extension wall 412b. As an example embodiment, the extension wall 412b has a length substantially identical to a thickness of the rigid substrate 450.

A plurality of protrusions 412c downwardly extends from the reference face 412a to a length larger than the thickness of the rigid substrate 450, so that the protrusion 412c penetrates the rigid substrate 450, and an end portion of the protrusion 412c is protruded from a bottom surface of the rigid substrate 450. The protrusion 412c is thermally pressed against the bottom surface of the rigid substrate 450, to thereby be flattened on the bottom surface of the rigid substrate 450. Accordingly, the lens holder 410 is firmly bonded to the rigid substrate 450.

As a result, the top surface 450a of the rigid substrate 450 makes close contact with the reference face 412a of the lens holder 410, so that foreign matter, such as dust, is prevented from being supplied into the lens holder 410. The foreign matter is firstly prevented from being supplied into the lens holder 410 by the extension wall 412b making contact with the sidewall of the rigid substrate 450. The extension wall 412b also prevents horizontal shifting of the rigid substrate 450, to thereby align the rigid substrate 450 in a horizontal direction together with the protrusion 412c. The above-described adhesion of the rigid substrate 450 and the lens holder 410 ensures a high degree of sealing and improved stability even though a bonding agent such as an epoxy bonding agent is not interposed between the rigid substrate 450 and the lens holder 410. Furthermore, no bonding agent between the rigid substrate 450 and the lens holder 410 means that assembly errors, due to the bonding agent when assembling the lens holder 410 to the rigid substrate 450, may be eliminated, so that a focal distance adjustment tends to be much less required in the lens holder 410.

The barrel 414 is formed through an injection molding process together with the lens holder 412, and a light-receiving hole 414b is formed on a top surface 414a of the barrel 414. The light-receiving hole 414b has an inner diameter smaller than a diameter of the lens. A lens is inserted into the barrel 414 and is bonded to the barrel 414 by tightly inserting a light-shielding plate (not shown) into the barrel 414.

A holding structure 470 including a light source 490 is formed on an upper portion of the barrel 414 as one body.

A pad 450d to which an image sensor 460 is bonded is formed on the top surface 450a of the rigid substrate 450, and an insertion hole 450b is formed at the edge portion of the rigid substrate 450. The protrusion 412c of the lens holder 410 is inserted into the insertion hole 450b. A terminal (not shown) is formed on the bottom surface of the rigid substrate 450, and the rigid substrate 450 is electrically connected to the flexible substrate 452 through the terminal. The terminal is also electrically connected to the pad 450d on the top surface of the rigid substrate 450 through a conductive pattern that is formed at the rigid substrate 450.

The image sensor chip 460 includes a light-receiving window 460a on a top surface thereof, and a bonding pad is formed around the light-receiving window 460a. The bonding pad of the image sensor 460 is electrically connected to the pad 450d of the rigid substrate 450 by a wire bonding process.

The lens holder 410 is strongly assembled to the rigid substrate 450 by a thermal bonding of the protrusion 412c of the lens holder 412 to the bottom surface of the rigid substrate 450.

### Embodiment 4

### Epoxy Bonding Structure Between a Lens Holder and a Module Substrate

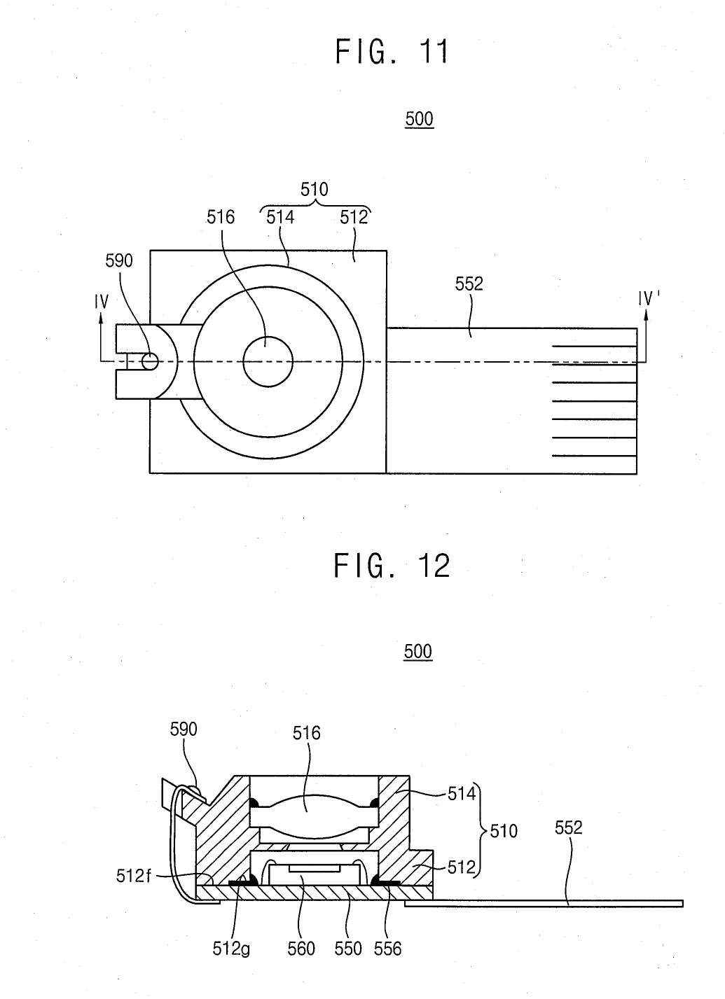

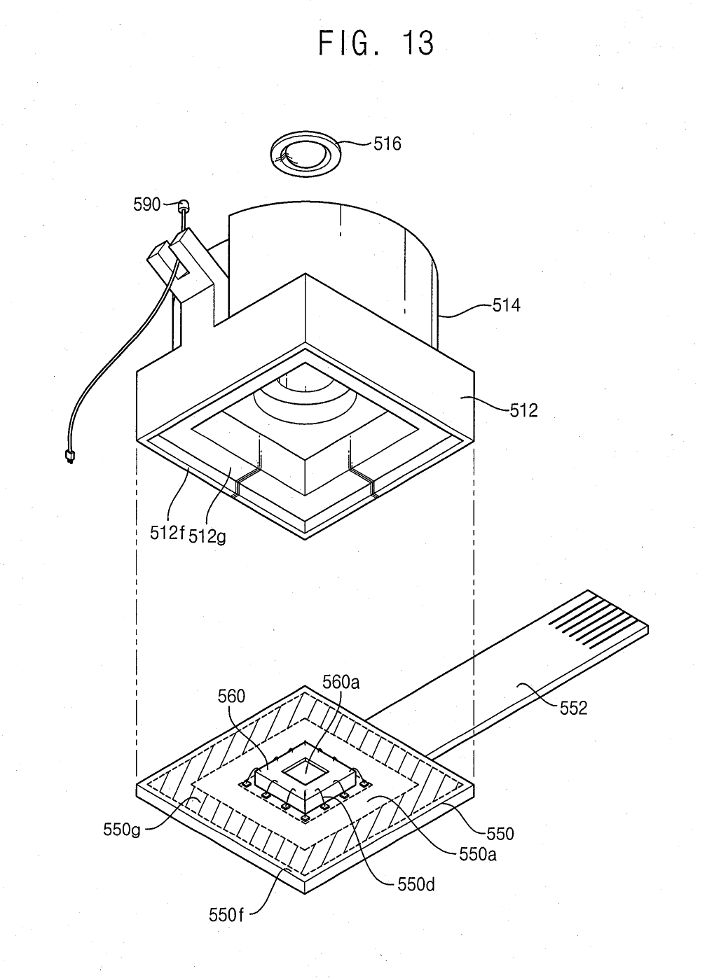

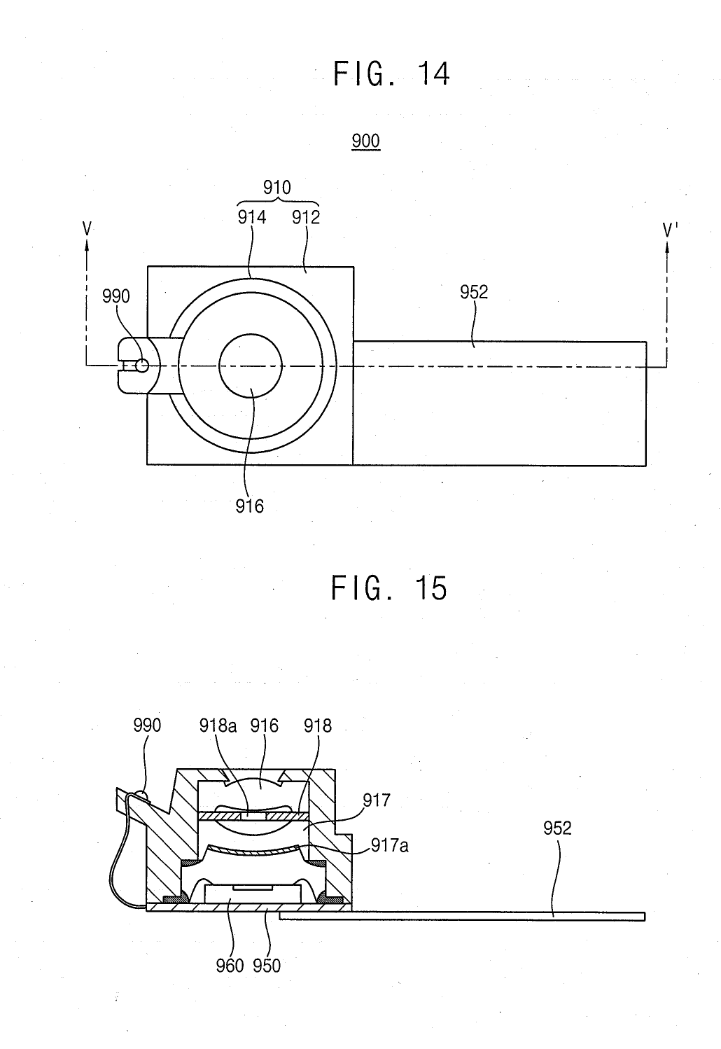

FIG. 11 is a plan view illustrating an optical sensor module according to a fourth example embodiment of the present invention, and FIG. 12 is a cross-sectional view taken along the line IV-IV′ of FIG. 11. FIG. 13 is an exploded perspective view illustrating the optical sensor module shown in FIG. 11.

The present example embodiment is different from Embodiment 3 in that the lens holder is bonded to the rigid substrate not by the thermal bonding process but by using an epoxy bonding agent.

A box-shaped receiving unit 512 of the lens holder 510 of the present embodiment includes a reference face 512f on the bottom surface thereof. The reference face 512f is substantially horizontal with respect to an optical axis 502, and makes contact with a top surface 550a of an edge portion 550f of the rigid substrate 550. An adjustment for a back-focus is performed on a basis of the reference face 512f.

A bonding surface 512g is formed on inner sidewalls of the receiving unit 512 upwardly stepped from the reference face 512f, so that the bonding surface 512g is higher than the reference face 512f by a predetermined gap distance. The bonding surface 512g makes contact with an epoxy bonding agent 556 that is coated on a bonding area 550g (represented as a dotted line in FIG. 13) of a top surface 550a of the rigid substrate 550, and the gap distance between the reference face 512f and the bonding surface 512g corresponds to a thickness of the epoxy bonding agent 556.

The epoxy bonding agent 556 is coated along an inner edge portion of the bonding area 550g of the rigid substrate 550, and is pressed down upon by the bonding surface 512g of the lens holder 510. Therefore, the epoxy bonding agent 556 is spread out from the inner edge portion of the bonding area 550g to an outer edge portion of the bonding area 550g. The spreading of the epoxy bonding agent 556 is adjusted in such a way that the epoxy bonding agent 556 is not interposed between the reference face 512f and the edge portion 550f of the rigid substrate 550.

In the present example embodiment, the epoxy bonding agent 556 comprises a low-temperature hardening epoxy that tends to be hardened at a temperature below about 80° C., so that a thermal effect on a plastic lens, which has been already installed in the barrel 514 of the lens holder 510 before the epoxy bonding agent 556, may be minimized during a hardening process for the epoxy bonding agent 556. An example of the low-temperature hardening epoxy bonding agent includes LPD-4391 (a product made by Loctite Co., Ltd. in the U.S.A.)

According to the present embodiment, the reference face of the lens holder functions as a base for a process without a focal distance adjustment, and the lens holder is firmly bonded to the rigid substrate by the low-temperature hardening epoxy bonding agent without any thermal effect on the plastic lens in the lens holder. In addition, the lens holder may be more tightly sealed off from surroundings due to the epoxy bonding agent, so that the contamination of the light-receiving window due to foreign matter, such as dust, is sufficiently prevented by the epoxy bonding agent.

### Embodiment 5

### Epoxy Bonding Structure Between a Lens Holder and a Module Substrate Including a Lens Combination, a Light-Shielding Plate and an IR-Cut Filter

FIG. 14 is a plan view illustrating an optical sensor module according to a fifth example embodiment of the present invention, and FIG. 15 is a cross-sectional view taken along the line V-V′ of FIG. 14.

Referring to FIGS. 14 and 15, the optical sensor module of the present embodiment is the same as in Embodiment 4 except for a lens combination including first and second lenses 916 and 917 and a light-shielding plate 918. The lens holder 910 includes a receiving unit 912 bonded to a rigid substrate 950 and a barrel 914 formed on the receiving unit 912 together with the barrel 914 as one body. A top portion of the barrel 914 includes a light-passing hole (not shown) of which a diameter is less than that of the first and second lenses 916 and 917, so that the lens combination is inserted inside of the barrel 914 and bonded to an inner surface of the barrel 914. The light-shielding plate 918 is interposed between the first and second lenses 916 and 917, and includes a central hole 918a at a center portion thereof. The central hole 918a prevents unessential light from being incident onto the second lens 917. The first and second lenses 916 and 917 are bonded to the inner surface of the barrel 914 by an ultraviolet bonding agent. An IR-cut filter 917a is formed on one of top and bottom surfaces of the second lens 917. The IR-cut filter 917a filters infrared is light from the incident light, thereby improving quality of an image on the receiving surface of the optical sensor chip 960.

Method of assembling the optical sensor module

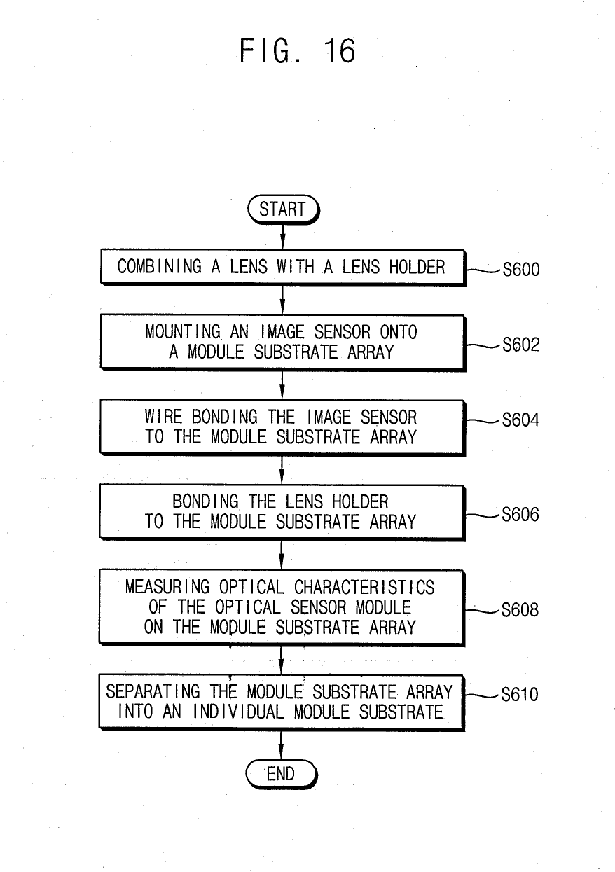

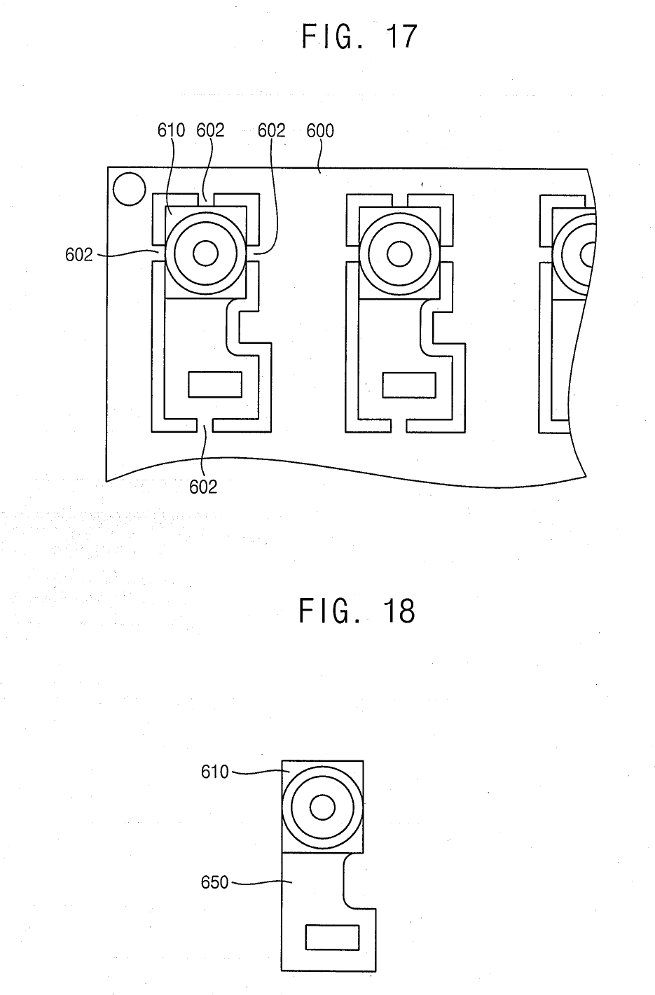

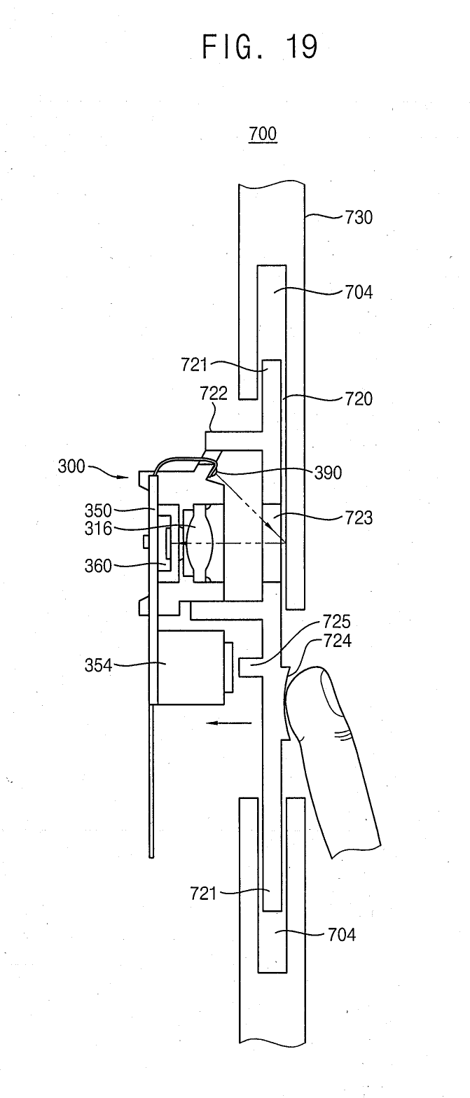

FIG. 16 is a flow chart illustrating a method of assembling the optical sensor module according to an example embodiment of the present invention. FIG. 17 is a view illustrating a module substrate array according to an example embodiment of the present invention, and FIG. 18 is a view illustrating an individual optical sensor module separated from the module substrate array shown in FIG. 17.

Referring to FIGS. 16 to 18, at least one lens is installed into a lens holder 610 (step S600), and an image sensor chip is mounted on each rigid substrate 650 of the module substrate array 600 shown in FIG. 17 in an image sensor assembler (step S602). Then, the image sensor chip is bonded to the rigid substrate 650 through a wire bonding process (step S604). The lens holder 610 is mounted on the rigid substrate 650 of the module substrate array 600 in a lens holder assembler, respectively by pressing, adhesion, locking or thermal bonding (step S606).

When the image sensor chip and the lens holder are installed in the rigid substrate, optical characteristics of the optical sensor module are measured in an optical test instrument (step S608). The optical characteristics are measured on the module substrate array before separating into individual optical sensor modules, which enables an automatic measurement for the optical characteristics. As a result, the measurement time is remarkably reduced to thereby reduce the assembly costs of the optical sensor module.

When the optical characteristics measurement is completed, each connector 602 of the module substrate array 600 is cut off by a divider, so that each optical sensor module is separated from the module substrate array 600 (step S610).

The separated optical sensor module is assembled into the body of the optical mouse.

B. Direction Key-Type Optical Mouse—Application to a Cellular Phone

FIG. 19 is a cross-sectional view illustrating a slide-type optical coordinate input apparatus according to an example embodiment of the present invention. The slide-type optical coordinate input apparatus 700 of the present embodiment corresponds to the image sensor module in Embodiment 3 that is adopted as a directional key of a cellular phone.

A frame 730 of the cellular phone includes a recessed portion 704 in which a driving plate 720 is inserted, a holder 722 for holding the image sensor module 300 and a hole 723 through which a light irradiated from a light source 390 such as an LED reaches the frame 730. In addition, the frame 730 of the cellular phone includes a finger contact portion 724 and button rib 725 for selectively making contact with a switch 354.

According to the present embodiment, an optical image formed by the LED on the driving plate 720 moves according as the driving plate 720 selectively moves along one of left, right, up and down directions, and the movement of the optical image is detected by the image sensor through the lens 316. Then, the movement of the optical image is transferred into a movement of a cursor on a screen, so that the cursor moves on the screen by as much as the detected amount of the optical image movement. When the cursor movement is completed, the driving plate 720 is pressed by a finger of a user to thereby turn on the switch 354. As an example embodiment, the image sensor module 300 is connected to the body of the optical coordinate input apparatus using a flexible substrate or a cable, so that the image sensor module 300 is able to be moved freely.

C. Ball-Type Optical Mouse

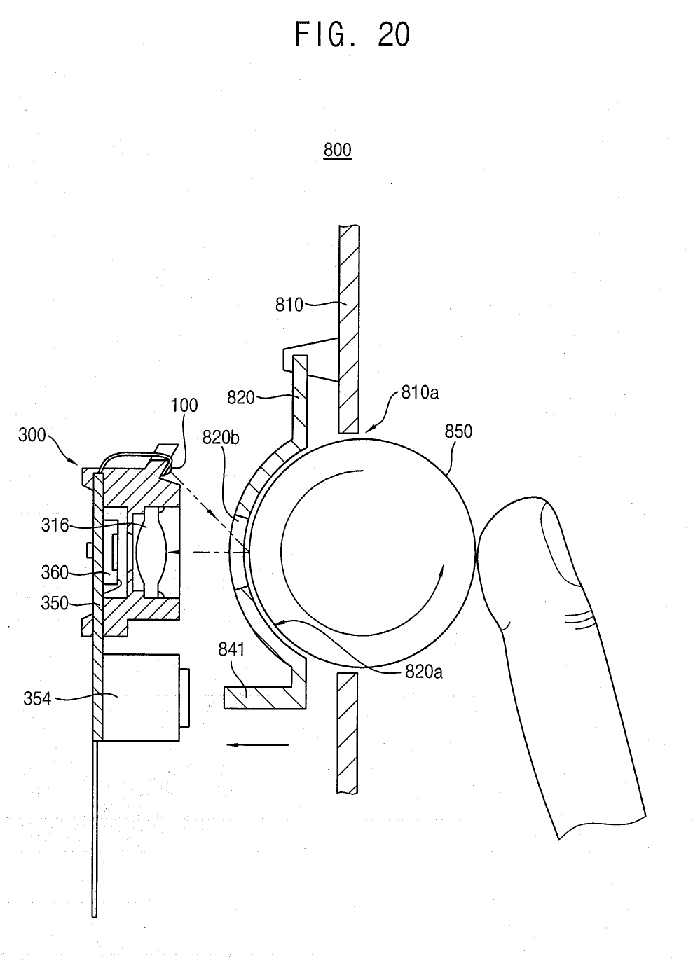

FIG. 20 is a cross-sectional view illustrating a ball-type optical coordinate input apparatus according to an example embodiment of the present invention. The ball-type optical coordinate input apparatus 800 of the present embodiment utilizes a rotational ball 850 in place of the driving plate 720 of the slide-type optical coordinate input apparatus 700. A receiving hole 810a for receiving the ball 850 is formed on a frame of a cellular phone, and more particularly, on a directional keyboard of the cellular phone. An inner diameter of the receiving hole 810a is smaller than that of the rotating ball 850, so that the rotating ball 850 is sufficiently prevented from being detached from the receiving hole 810a. An end portion of a cantilever 820 is bonded to the frame 810, and includes a holding groove 820a corresponding to circumferential portion of the ball 850. A transparent window 820b is formed on the holding groove 820a. The image sensor module 300 is fixed to a predetermined position. An optical image on the rotating ball moves according as the ball 850 rotates, and the movement of the optical image is detected by the image sensor 360 through the lens 316. Then, the movement of the optical image is transferred into a movement of a cursor on a screen, so that the cursor moves on the screen by as much as the detected amount of the optical image movement. When the cursor moves on the screen completely, the rotating ball 850 is pressed by a finger of a user, and a button rib 841 protruded from the holding groove 820a makes contact with a switch 354 of the image sensor module 300 to thereby turn on the switch 354.

This invention has been described with reference to the example embodiments. It is evident, however, that many alternative modifications and variations will be apparent to those having skill in the art in light of the foregoing description. Accordingly, the present invention embraces all such alternative modifications and variations as fall within the spirit and scope of the appended claims. For example, various modifications would be allowable at the various parts of the camera module of the present invention such as a bonding structure of the lens holder and the substrate, an IR cut coating structure for protecting the lens and the image sensor, lens combinations, a structure of the flexible substrate and the supplementary plate and auto-focusing lens combinations. In addition, a non-spherical single lens would be utilized in place of the lens combinations in the lens holder, as would be known to one of ordinary skill in the art.

### INDUSTRIAL APPLICABILITY

According to the present invention, a downsized optical sensor module can be mounted on an optical coordinate input apparatus at a low cost, so that the optical coordinate input apparatus such as a pen-type optical mouse and a cellular phone may be easily assembled without having to be limited by the sizes of embodied parts thereof. As a result, the optical coordinate input apparatus may be manufactured with unlimited and various designs.

1. An optical coordinate input apparatus comprising:
a body including an opening portion adjacent to a reflective surface;
a circuit board installed in the body; and
an optical sensor module that is installed in the body adjacent to the opening and separately from the circuit board, the optical sensor module having a light-receiving surface, of which an incident optical axis is inclined with respect to the reflective surface and a light source, of which an exiting optical axis is inclined with respect to the incident optical axis.

2. The optical coordinate input apparatus of claim 1, wherein a shape of the body resembles that of a pen and the optical sensor module is installed at a pointed portion of the pen-shaped body.

3. The optical coordinate input apparatus of claim 1, wherein the exiting optical axis is inclined with respect to the incident optical axis at an angle of about 20°±5°.

4. The optical coordinate input apparatus of claim 1, wherein the optical sensor module includes a module substrate on which a lens holder having the light source and at least one lens and an image sensor having the light-receiving surface are installed,
wherein the lens holder includes a barrel having a receiving groove for receiving a light source at an outer surface thereof, and a box-shaped receiving unit that is combined together with the barrel as one body,
wherein a bottom surface of the receiving unit is arranged perpendicular with respect to an optical axis of the lens and makes contact with an edge portion of a top surface of the module substrate, to thereby function as a reference face for a focal distance between the lens and the light-receiving surface, and a plurality of protrusions downwardly extends from an inner edge portion of the bottom surface of the receiving unit to a length larger than a thickness of the module substrate, so that each of the protrusions penetrates the module substrate and an end portion of each of the protrusions is protruded from the bottom surface of the module substrate,
wherein a plurality of insertion holes through which the protrusions are inserted is formed at an edge portion of the module substrate.

5. The optical coordinate input apparatus of claim 4, wherein the lens holder is bonded to the module substrate by pressing, adhesion, locking or thermal bonding.

6. The optical coordinate input apparatus of claim 1, wherein the optical sensor module includes:
a module substrate of which a top surface is substantially perpendicular to an optical axis;
a lens holder including a barrel having a receiving groove formed at an outer surface thereof and a box-shaped receiving unit that is combined together with the barrel as one body;
a light source received in the receiving groove;
a lens installed in the barrel; and
an image sensor positioned in a sealed space between the receiving unit and the module substrate and mounted on a top surface of the substrate,
wherein a bottom surface of the receiving unit is arranged perpendicular with respect to an optical axis of the lens and makes contact with a top surface of the substrate to thereby function as a reference surface for a focal distance between the lens and the light-receiving surface.

7. The optical coordinate input apparatus of claim 6, wherein the module substrate includes:
an extension portion outwardly extending over the lens holder; and
a switch on the extension portion.

8. The optical coordinate input apparatus of claim 7, wherein the body is shaped into a pen, and a pen point is positioned at a pointed portion of the body such that the pen point is vertically protruded from the reference surface and moves forwardly and backwardly, so that the switch is operated in accordance with the movement of the pen point.

9. The optical coordinate input apparatus of claim 1, wherein the body includes a camera module.

10. The optical coordinate input apparatus of claim 2, wherein the circuit board includes:
a wireless transmission module for transmitting detected coordinates;
an internal battery for supplying power to the circuit board; and
a plurality of terminals for connecting an external power source to the internal battery.

11. An optical sensor module for an optical coordinate input apparatus, comprising:
a module substrate of which a top surface is substantially perpendicular to an optical axis;
a lens holder including a barrel having a receiving groove formed at an outer surface thereof and a box-shaped receiving unit that is combined together with the barrel as one body;
a light source received in the receiving groove;
a lens installed in the barrel; and
an image sensor positioned in a sealed space between the receiving unit and the module substrate and mounted on a top surface of the substrate,
wherein a bottom surface of the receiving unit is arranged perpendicular with respect to an optical axis of the lens and makes contact with a top surface of the substrate to thereby function as a reference surface for a focal distance between the lens and the light-receiving surface, and a plurality of protrusions downwardly extends from an inner edge portion of the bottom surface of the receiving unit to a length larger than a thickness of the module substrate, so that each of the protrusions penetrates the module substrate and an end portion of each of the protrusions is protruded from the bottom surface of the module substrate,
wherein a plurality of insertion holes through which the protrusions are inserted is formed at an edge portion of the module substrate.

12. The optical sensor module of claim 11, wherein the lens holder is bonded to the module substrate by pressing, adhesion, locking or thermal bonding with respect to the protrusions.

13. An optical sensor module for an optical coordinate input apparatus, comprising:
a module substrate of which a top surface is substantially perpendicular to an optical axis;
a lens holder including a barrel having a receiving groove formed at an outer surface thereof and a box-shaped receiving unit that is combined together with the barrel as one body;
at least one lens installed in the barrel;
a light-shielding plate installed in the barrel; and
an image sensor positioned in a sealed space between the receiving unit and the module substrate and mounted on a top surface of the substrate,
wherein a bottom portion of the receiving unit includes a reference surface that is substantially perpendicular with respect to the optimal axis and makes direct contact with a top surface of the substrate, and a bonding surface that is spaced apart from the top surface of the substrate by a predetermined gap distance and makes direct contact with a bonding agent in the gap distance.

14. The optical sensor module of claim 13, further comprising a light-emitting diode (LED) installed in the receiving groove.

15. The optical sensor module of claim 13, wherein an infrared (IR) cut filter is coated on at least one surface of the lens.

16. A method of assembling an optical sensor module, comprising:
combining a lens with a lens holder;
mounting an image sensor on each module substrate of a module substrate array;
combining the lens holder including the lens with each of the module substrates of the module substrate array;
measuring optical characteristics of each optical sensor module on each module substrate; and
separating the module substrate array into individual module substrates.

17. An optical coordinate input apparatus comprising:
a housing including a fixing member;
a moving member installed in the housing and which moves along upward, downward, leftward or rightward directions; and
an optical sensor module installed in the moving member, the optical sensor module irradiating onto the fixing member and detecting a reflected image reflected from the fixing member.

18. An optical coordinate input apparatus comprising:
a fixing member including a receiving hole;
a cantilever of which an end portion is connected to the fixing member, the cantilever including a holding groove having a transparent window on an inner surface thereof;
a rotating ball rotatably positioned in the receiving hole of the fixing member and the holding groove of the cantilever; and
an optical sensor module for irradiating a light to the rotating ball through the transparent window and detecting a reflected image reflected from the rotating ball.
